(19) United States
(12) Patent Application Publication
(10) Pub. No.: US 2026/0367521 A1
(43) Pub. Date: Nov. 19, 2026

(54) METHOD AND SYSTEM FOR GAS DEVELOPMENT OF METAL OXIDE PHOTORESIST

(71) Applicant: Tokyo Electron Limited, Tokyo (JP)

(72) Inventors: Joshua Baillargeon, Albany, NY (US); Hamed Hajibabaeinajafabadi, Albany, NY (US)

(21) Appl. No.: 19/208,017

(22) Filed: May 14, 2025

(51) Int. Cl. G03F 7/36; G03F 7/004; H01J 37/32

(52) U.S. Cl. CPC G03F 7/36; G03F 7/0043; H01J 37/3244; H01J 37/32816; H01J 2237/334; H01J 2237/335

(57) ABSTRACT

A method for gas development includes removing a first part of a first region of a metal oxide resist (MOR) layer with a first gas development process, disrupting an etch stop layer formed over a second part of the first region with a plasma treatment using a multi-atomic gas having vibrational modes, and removing the second part of the first region with a second gas development process.

### TECHNICAL FIELD

The present invention relates generally to semiconductor manufacturing, and, in particular embodiments, to a system and method for gas development of metal oxide photoresists (MORs).

### BACKGROUND

In the semiconductor industry, photolithography is commonly used in the fabrication of integrated circuits, with metal oxide resists (MOR), also referred to as metal oxide photoresists, emerging as a valuable material for advanced patterning processes due to their high resolution and etch resistance properties. Traditionally, photoresists are developed using wet chemical processes. However, gas-based development techniques have gained attention for their potential to pattern smaller structures (for example, line/space and pillars) without the drawback of capillary forces that can cause pattern collapse. In gas development of MOR, a gas or vapor is used to selectively remove exposed or unexposed areas of the photoresist, creating the desired pattern. This process involves complex interactions between the development chemistry and the metal oxide components of the photoresist.

The development of metal oxide resist (MOR) patterns benefits from precise control and high selectivity between exposed and non-exposed regions. Conventional gas-phase development (GDEV) processes using hydrogen bromide (HBr) at high temperatures can achieve high throughput and low defectivity but often have poor selectivity and result in undesirable inverse taper of the MOR patterns. In contrast, conventional gas-phase development (GDEV) processes using hydrogen bromide (HBr) at low temperatures can achieve good selectivity and dose-to-size control but often result in the formation of an undesirable etch stop layer (ESL) in some materials that may increase the remaining thickness of the MOR in regions to be removed by development. Current solutions to address the ESL formation, such as gas pulsing or temperature cycling, significantly impact manufacturing throughput and may compromise pattern quality. Additionally, as semiconductor devices continue to shrink and require more precise patterning, traditional development processes struggle to meet the demanding requirements for line edge roughness (LER) and line width roughness (LWR) while maintaining high throughput.

The semiconductor industry faces increasing pressure to develop more efficient and effective patterning processes, particularly as competition intensifies in the track business with the promotion of chemical vapor deposition (CVD) and development processes for advanced technologies utilizing extreme ultraviolet (EUV) lithography. Current temperature cycling methods to remove the ESL create throughput bottlenecks in the manufacturing process, while maintaining the necessary selectivity and pattern fidelity remains challenging with existing development techniques.

### SUMMARY

In accordance with an embodiment, a method for gas development includes: removing a first part of a first region of a metal oxide resist (MOR) layer with a first gas development process; disrupting an etch stop layer formed over a second part of the first region with a plasma treatment using a multi-atomic gas having vibrational modes; and removing the second part of the first region with a second gas development process.

In accordance with another embodiment, a method for gas development of a metal oxide photoresist includes: exposing a metal oxide resist layer to light through a photomask; selectively removing portions of non-exposed regions of the metal oxide resist layer with a first etch process; removing an etch stop layer formed over remaining portions of the non-exposed regions with a plasma generated using a gas having at least one vibrational mode; and selectively removing the remaining portions of the non-exposed regions with a second etch process.

In accordance with yet another embodiment, a system includes: a process chamber configured to receive a substrate having an exposed metal oxide resist (MOR) layer; a gas delivery system coupled with the process chamber, the gas delivery system being configured to supply a development gas and a multi-atomic process gas; and a controller coupled with the process chamber, the gas delivery system, and a memory storing instructions to be executed in the controller, the instructions when executed causing the controller to: perform a first gas development process on unexposed MOR material of the exposed MOR layer with the development gas, disrupt an etch stop layer formed during the first gas development process using a plasma treatment performed with the multi-atomic process gas, and perform a second gas development process on a portion of the unexposed MOR material below the etch stop layer with the development gas.

It is to be understood that both the foregoing general description and the following detailed description are exemplary and explanatory only and are not restrictive of the disclosure, as claimed.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1, 2, 3, 4, 5A, 6, and 7 illustrate cross-sectional views of a substrate during intermediate steps of a gas development process, in accordance with some embodiments;

FIG. 5B illustrates a table of vibrational modes of various process gases, in accordance with some embodiments;

FIGS. 8 and 9 illustrate graphs of experimental results for gas development processes, in accordance with some embodiments;

FIG. 10 illustrates a system diagram of a processing system capable of implementing processing methods comprising a gas development process in accordance with some embodiments;

FIG. 11 illustrates a process flow chart diagram of a method for gas development, in accordance with some embodiments; and

FIG. 12 illustrates a process flow chart diagram of a method for gas development of a metal oxide photoresist, in accordance with some embodiments.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

In the field of semiconductor manufacturing, metal oxide resists (MOR) are utilized for patterning processes on substrates. Gas development techniques with gases such as HBr are employed to reveal patterns in these photoresists. However, the current gas development processes for MOR face several challenges. Low temperature gas development (e.g., with HBr) can yield good MOR selectivity and improved dose-to-size, but it may induce formation of an undesirable etch stop layer (ESL) within the unexposed MOR region that should desirably be removed or disrupted. Although undesirable etch stop layers may be disrupted by temperature cycling with, for example, electrostatic chuck heating of the substrate, this may disadvantageously hinder throughput.

According to one or more embodiments of the present disclosure, this application relates to methods of selective gas development of metal oxide resists (MORs) by thermal treatments. Disruption of undesirable etch stop layers can be achieved by using gas properties in thermal treatments. For example, vibrationally active molecules (e.g., multi-atom molecules such as diatomic molecules, triatomic molecules, or the like) can promote enhanced heating (such as through collision or radiation). This can disrupt or possibly remove etch stop layers with minimal impact to bulk film properties (e.g., of the MOR). In some embodiments, plasma is struck to perform the thermal treatment. Some prior attempts to use plasma in gas development of MOR have produced undesirable results such as aggressive film modification that yields minimal chemical contrast between exposed and non-exposed portions of the films. The application of multi-atomic molecules to leverage vibrational energy enables the use of plasma for etch stop layer disruption during selective gas development. As such, including intermediate steps of thermal treatment with multi-atomic gases during low temperature gas development can achieve good MOR selectivity and improved dose-to-size while disrupting or removing etch stop layers that may cause defectivity and throughput loss.

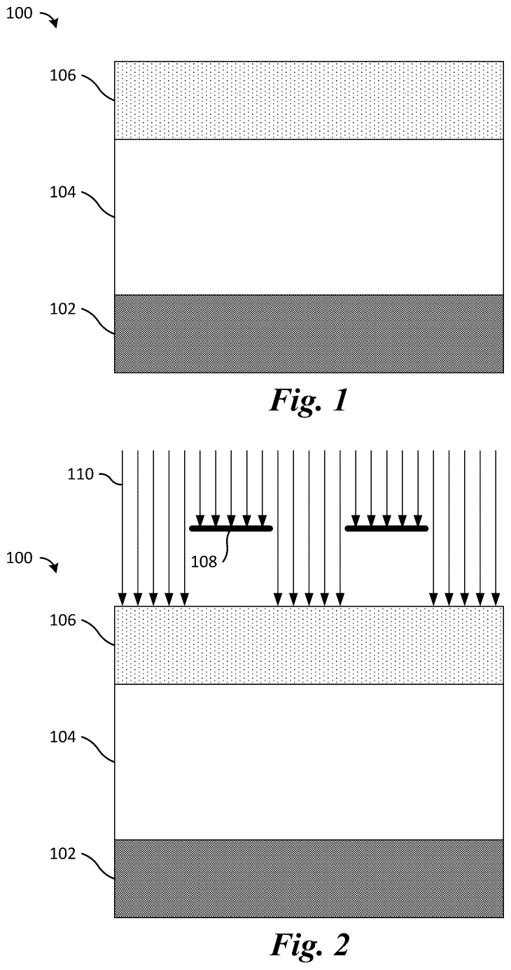

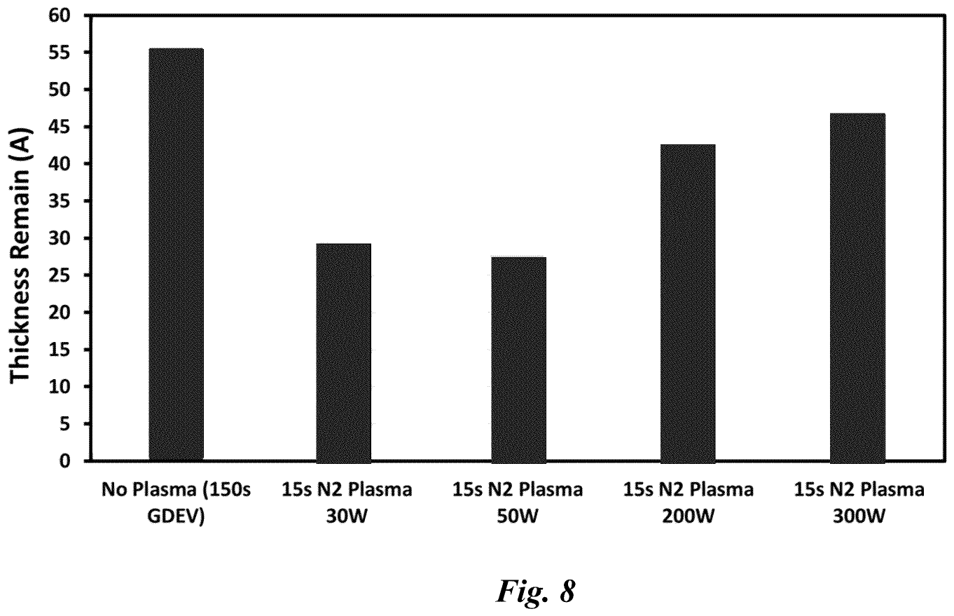

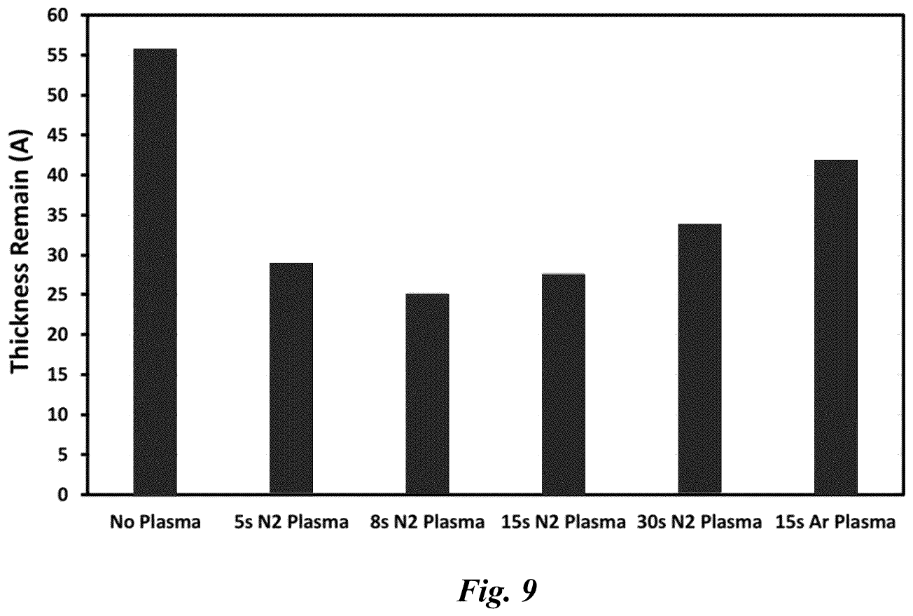

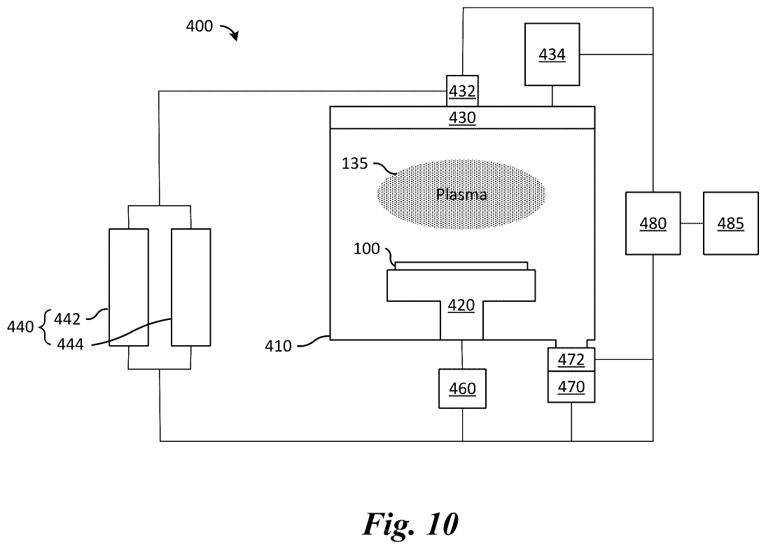

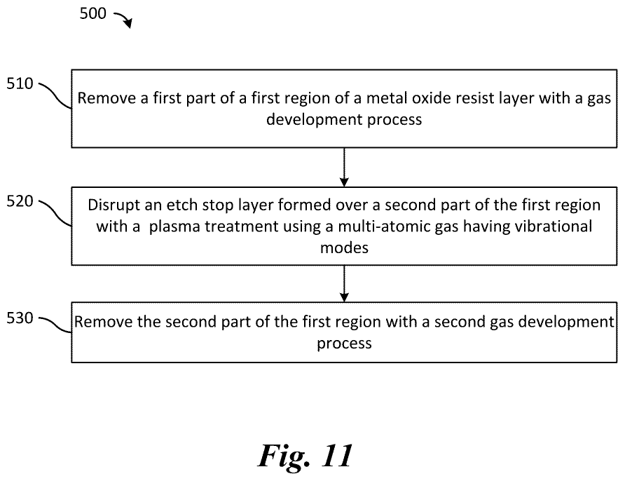

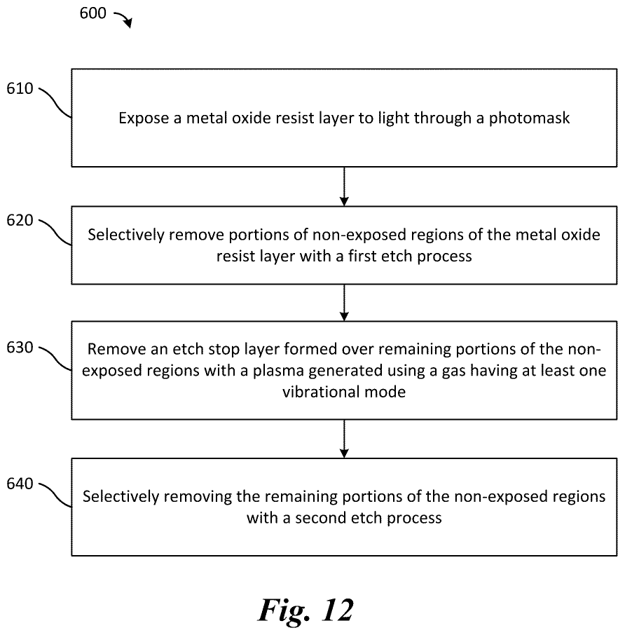

Embodiments of the disclosure are described in the context of the accompanying drawings. Embodiments of a processing method for removing undesired portions of a metal oxide photoresist layer will be described using FIGS. 1, 2, 3, 4, 5A, 5B, 6, and 7. Experimental results for gas development processes will be described using FIGS. 8 and 9. Embodiments of a processing system capable of implementing processing methods comprising a gas development process will be described using FIG. 10. Embodiments of methods for gas development will be described using FIGS. 11 and 12.

FIGS. 1, 2, 3, 4, 5A, 6, and 7 illustrate cross-sectional views of a substrate 100 during intermediate steps of a processing method for removing undesired portions of a metal oxide photoresist layer, in accordance with some embodiments of this disclosure.

FIG. 1 illustrates a cross-sectional view of an example substrate 100 which may be used in the processing method of this disclosure. The substrate 100 comprises a substrate base 102, an underlying layer 104 disposed over the substrate base 102, and a metal oxide photoresist (MOR) layer 106 deposited over the underlying layer 104. In one or more embodiments, FIG. 1 illustrates the substrate 100 after it has been received in a photolithography tool for subsequent exposure and development of the MOR layer 106, as described below with respect to FIG. 2.

In various embodiments, the underlying layer 104 and the MOR layer 106 have been deposited through conventional deposition methods before the substrate 100 is received in the photolithography tool. For example, the underlying layer 104 may be deposited through a suitable deposition process such as a plasma deposition process, an atomic layer deposition (ALD) process, a chemical vapor deposition (CVD), a plasma-enhanced chemical vapor deposition (PECVD) process, the like, or a combination thereof. In some embodiments, after depositing the underlying layer 104, a planarization process is performed to planarize the underlying layer 104 before depositing the MOR layer 106. Further, the MOR layer 106 may be deposited through a suitable deposition process for the MOR layer 106 such as a spin coating method or gas phase deposition techniques such as an ALD process or a CVD process.

In one or more embodiments, the substrate base 102 comprises silicon, silicon oxide, or other suitable materials commonly used in semiconductor manufacturing. In various embodiments, the underlying layer 104 comprises various materials depending on the specific application, such as dielectric materials, conductive materials, organic or various other semiconductor materials, the like, or a combination thereof. For example, the underlying layer 104 may comprise a film stack for forming a memory device. In various embodiments, the underlying layer 104 has a pattern transferred into it through a suitable etching process in subsequent processing steps. The MOR layer 106 comprises a photosensitive material that can be patterned through exposure to light and subsequently used as a mask for further processing steps after patterning. In some embodiments, the MOR layer 106 comprises tin (Sn), oxygen/hydroxide (O/OH), and organic components (saturated/unsaturated hydrocarbon). In various embodiments, the MOR layer 106 comprises tin oxide, hafnium based MORs (such as hafnium oxide), zirconium based MORs (such as zirconium oxide), titanium based MORs (such as titanium oxide), mixed metal MORs (such as hafnium zirconium oxide), the like, or a combination thereof.

In various embodiments, the MOR layer 106 comprises negative tone metal oxide photoresists, which may have photoactive ligands that are cleaved or removed when exposed to patterning light such that regions exposed to the patterning light are more difficult to remove after a high temperature bake. In other embodiments, the MOR layer 106 comprises positive tone metal oxide photoresists, which may weaken when exposed to patterning light such that regions exposed to the patterning light are easier to remove. As a non-limiting example, FIGS. 1, 2, 3, 4, 5A, 6, and 7 illustrate embodiments where the MOR layer 106 comprises negative tone MOR and the unexposed regions of the MOR are removed by a gas development process. However, an MOR layer 106 comprising positive tone MOR such that the exposed regions of the MOR are removed by a gas development process is also within the scope of the disclosed embodiments.

As described above, the substrate 100 illustrated by FIG. 1 may represent an initial stage in a photolithography process, where the MOR layer 106 is yet to be exposed to patterning light. This configuration forms the basis for subsequent processing steps, such as development (which may also be followed by etching), to create desired patterns on the substrate 100.

FIG. 2 illustrates the next step in the processing method, in which conventional techniques are employed to develop the MOR layer 106 shown in FIG. 1 through exposure to light beams 110. In the step illustrated in FIG. 2, a photo mask 108 is positioned above the substrate 100. The photo mask 108 comprises a predetermined pattern (feature pattern) that will be transferred to the MOR layer 106.

In various embodiments, light beams 110 are directed towards the photo mask 108. These light beams 110 may comprise ultraviolet (UV) light, extreme ultraviolet (EUV) light, or other suitable wavelengths depending on the photolithography process. In various embodiments where the light beams 110 comprise UV light, the photo mask 108 selectively blocks or allows the passage of light beams 110, creating a pattern of exposed and unexposed regions on the MOR layer 106. In other embodiments where the light beams 110 comprise EUV light, the photo mask 108 selectively reflects or allows the passage of light beams 110, creating the pattern of exposed and unexposed regions on the MOR layer 106.

The light beams 110 that pass through the photo mask 108 interact with the MOR layer 106, initiating photochemical reactions in the exposed regions. This interaction alters the chemical properties of the exposed regions, creating a chemical contrast or difference between the exposed and unexposed regions. The chemical contrast or difference thereby changes the relative etch properties of the exposed regions for a subsequent development process, depending on whether the MOR is a positive tone or negative tone resist. In the one or more embodiments illustrated by FIG. 2, the MOR layer 106 comprises negative tone MOR, which makes the exposed regions more difficult to remove after the exposure to the light beams 110.

In some embodiments, the exposure time and intensity of the light beams 110 are carefully controlled to ensure proper patterning of the MOR layer 106. The precise control of these parameters helps achieve the desired resolution and fidelity of the pattern transfer process.

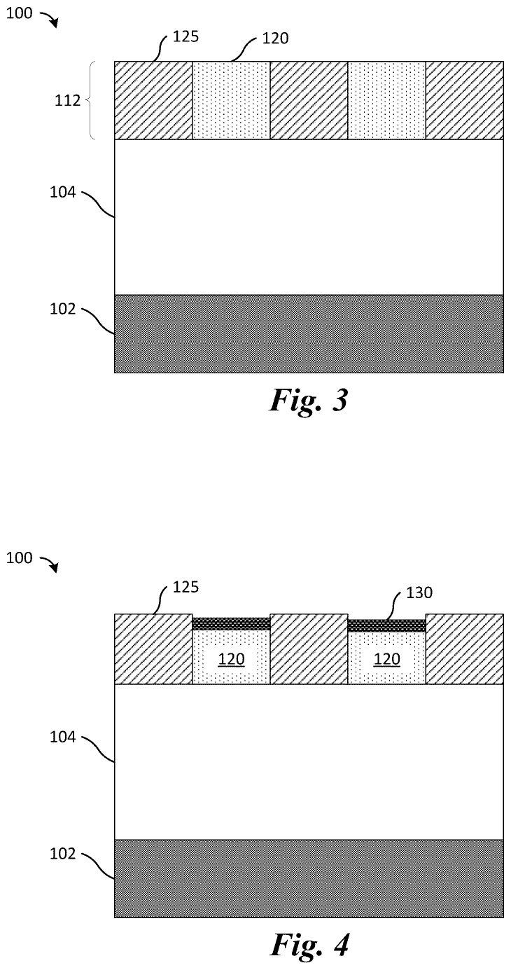

FIG. 3 illustrates the substrate 100 following the exposure of the previously unexposed MOR layer 106. This step illustrates the outcome of the photolithography process illustrated in FIG. 2. The substrate 100 now comprises a patterned MOR layer 112 resulting from the selective exposure of the MOR layer 106.

The exposure to the patterning light in FIG. 2 formed first regions and second regions in the patterned MOR layer 112, where the first regions are unexposed MOR regions 120, and where the second regions are exposed MOR regions 125. The exposed MOR regions 125 correspond to areas of the MOR layer 106 that were exposed to the light beams 110 (see above, FIG. 2). The unexposed MOR regions 120 corresponds to areas of the MOR layer 106 that were protected by the opaque parts of the photo mask 108 during the light exposure step.

The unexposed MOR regions 120 (the first regions) and exposed MOR regions 125 (the second regions) may be used to create a feature pattern on the substrate 100 that mirrors the design of the photo mask 108 used in the previous step. In various embodiments, the feature pattern represents features such as trenches, vias, or other structures suitable for the functionality of the final device.

The processing method illustrated by FIGS. 1, 2, 3, 4, 5A, 6, and 7 uses a gas development process to remove the first regions (the unexposed MOR regions 120) to form the feature pattern in the patterned MOR layer 112, which is described using FIGS. 4, 5B, and 6 below.

FIG. 4 illustrates the substrate 100 following a first step of a gas development process applied to remove undesired portions of the MOR layer 106. This stage represents a further refinement of the feature pattern started in the previous photolithography steps. The first step of a gas development process is also referred to as a first etch process.

In various embodiments, the gas development process involves exposing the substrate 100 to a reactive gas or gas mixture. This gas interacts with the undesired portions of the MOR layer 106 to chemically alter a first region (or the unexposed MOR region 120) of the MOR layer 106, facilitating their removal from the substrate surface. The process selectively etches the unexposed MOR regions 120 while leaving the exposed MOR regions 125 largely intact. The selectivity of the gas mixture used in the gas development process enables the targeted removal of either the exposed MOR regions 125 or unexposed MOR regions 120 as desired. Though the gas development process uses a selective gas mixture to remove undesired portions of the MOR layer 106, the process may still remove desired portions, just at a slower rate. The selectivity refers to removing the undesired portions of the MOR layer 106 at a faster rate than desired portions.

During the gas development process, factors such as gas composition, pressure, temperature, and exposure time are carefully controlled to achieve improved pattern resolution and reduce potential damage to the MOR layer 106. In one or more embodiments, the development gas used comprises halogen-containing compounds, oxygen-based gases, or other reactive species depending on the specific chemistry of the MOR layer 106. For example, in some embodiments, the development gas comprises hydrogen bromide (HBr), hydrogen chloride (HCl), hydrogen iodide (HI), organic or inorganic acids including acetic acid, chloroacetic acid groups, bromoacetic acid groups, fluoroacetic acid groups, acetylacetone, hexafluoroacetylacetone, the like, or a combination thereof. The development gas may further comprise a noble gas (helium, argon, or the like) that is flowed together with the reactive species as a diluent. In other embodiments, the development gas used comprises nitrogen, hydrogen, and one or more noble gas(es) such as helium, argon, or the like, and the gas may be exposed to the MOR layer 106 at a first temperature to chemically alter a surface region of the MOR layer 106. After, the substrate 100 may be raised to a second temperature to remove the chemically treated surface region of the MOR layer 106.

In one or more embodiments, the first step of the low temperature gas development process is performed at a temperature in a range of −50 °C to 100 °C, or in a range of 0 °C to 20 °C, such as about 10 °C. The low temperature enables high selectivity between the exposed MOR regions 125 and unexposed MOR regions 120. In various embodiments, the first step of the low temperature gas development process is performed under a pressure in a range of 50 mTorr to 5000 mTorr. In some embodiments, the gas development process comprises flowing HBr gas at a flow rate in a range of 150 sccm to 1500 sccm. In various embodiments, the gas development process is performed for a duration in a range of 30 seconds to 300 seconds, such as about 90 seconds. However, any suitable process conditions may be used to perform the first step of the low temperature gas development process.

This gas development step enhances the overall quality of the patterned MOR layer by removing undesired regions (or portions) of the MOR layer 106 after the photolithography and improving the edge definition of the exposed MOR regions 125. However, the gas development process described using FIG. 4 may produce an etch stop layer 130 over remaining portions of the unexposed MOR regions 120, which can affect subsequent processing steps. The ESL 130 comprises reaction products from the interaction between the HBr gas and the MOR material. Although the ESL 130 is referred to as a layer, the ESL 130 may be, for example, a surface level chemical composition that slows or stops a subsequent etch process rather than a layered structure. The ESL 130 formation during the low temperature gas development process impacts the removal rate of the unexposed MOR regions 120. In various embodiments, the ESL 130 comprises bromine-containing compounds that form a protective layer, limiting further removal of underlying MOR material.

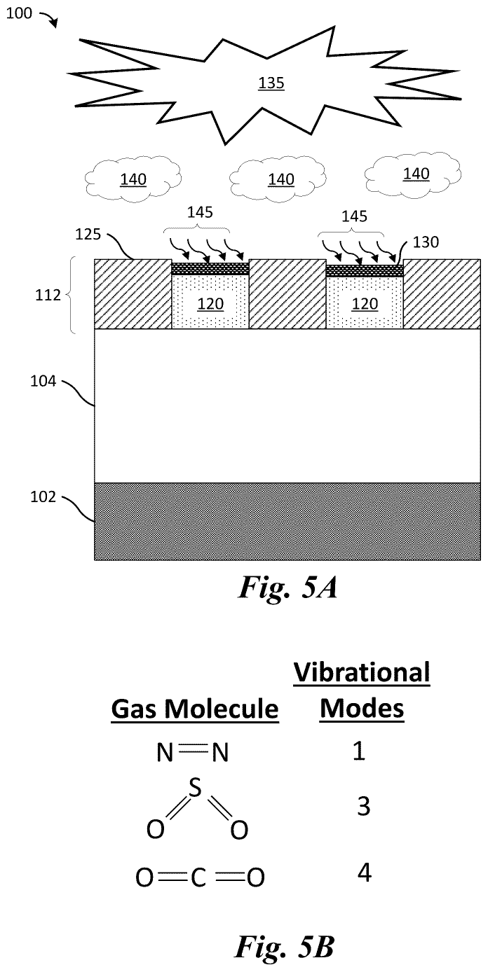

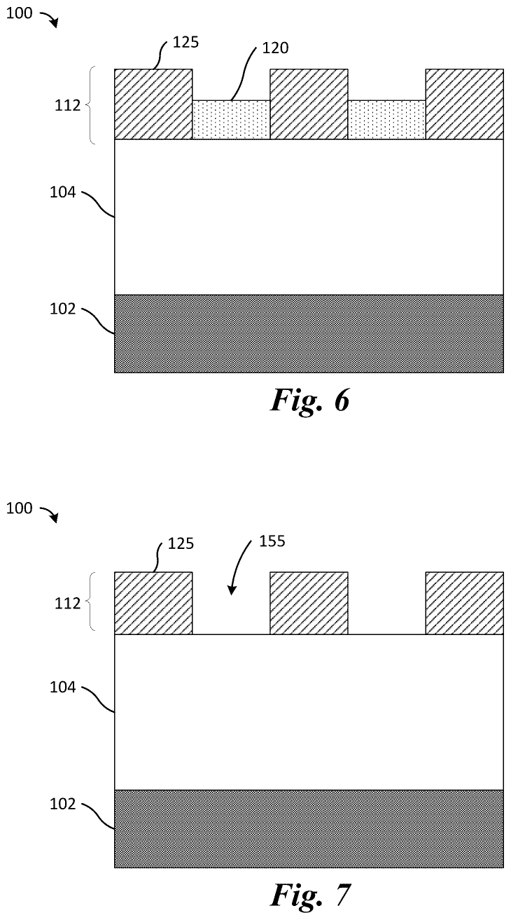

When the unexposed MOR regions 120 are not completely removed, defects may form in subsequent processing steps of the fabrication process, such as a subsequent etching step (see below, FIG. 6). Additionally, outgassing from the MOR layer 106 may continue after the gas development process. As such, it is desirable to disrupt or remove the ESL 130 in order to achieve greater or complete removal of the unexposed MOR regions 120 as described below with respect to FIG. 5A.

FIG. 5A illustrates a cross-sectional view of the substrate 100 during a thermal plasma treatment process step performed after the first step of the low temperature gas development process as described above with respect to FIG. 4. The thermal plasma treatment (also referred to as a plasma treatment or a photo-thermal treatment) utilizes a multi-atomic molecule gas 140 (also referred to as a multi-atomic gas or a multi-atomic process gas) having at least one vibrational mode to generate thermal energy that disrupts or removes the ESL 130. In various embodiments, the multi-atomic molecule gas 140 comprises a multi-atomic single element gas such as nitrogen (N₂), multi-atomic molecules that include multiple elements such as sulfur dioxide (SO₂) and carbon dioxide (CO₂), the like, or a combination thereof.

In one or more embodiments, the thermal plasma treatment comprises generating a plasma 135 that enables molecular vibration in the multi-atomic molecule gas 140 when the plasma 135 is struck. The plasma treatment 135 generates thermal energy 145 through vibrational modes of the multi-atomic molecules of the multi-atomic molecule gas 140. This thermal energy 145 targets and disrupts the ESL 130. The selective use of multi-atomic molecules with vibrational modes enables a controlled disruption of the ESL 130 while preserving the chemical contrast between exposed and unexposed MOR regions for subsequent processing steps.

In some embodiments, the plasma treatment 135 is performed at a pressure in a range of 50 mTorr to 700 mTorr, such as about 500 mTorr, at a power of 30 W to 100 W, such as about 50 W, at a temperature in a range of 0 °C to 20 °C, such as about 10 °C, and for a duration in a range of 5 seconds to 15 seconds, such as about 8 seconds. These or other suitable process conditions create a soft plasma environment that reduces modification of the bulk MOR film properties.

FIG. 5B illustrates a table of vibrational modes of various process gases that may be utilized in the thermal plasma treatment described above with respect to FIG. 5A. The table displays a gas list illustrating N_{2,} SO₂, and CO₂ molecules along with their corresponding number of vibrational modes. In various embodiments, gases with multiple vibrational modes provide enhanced thermal energy generation during the thermal plasma treatment process through molecular stretching and bending mechanisms. As illustrated in FIG. 5B, N₂ exhibits one vibrational mode, SO₂ exhibits three vibrational modes, and CO₂ exhibits four vibrational modes. Gases with one or more vibrational modes may provide controlled thermal energy generation for ESL disruption while minimizing bulk film modification (see above, FIG. 5A).

FIG. 6 illustrates a cross-sectional view of the substrate 100 after performing a second step of a gas development process following the thermal plasma treatment described above with respect to FIG. 5A. The second step of a gas development process is also referred to as a second etch process. The additional gas development process step continues the removal of the unexposed MOR regions 120 after the disruption of the ESL 130 (see above, FIG. 5A) by the thermal plasma treatment. In various embodiments, with the ESL 130 disrupted or removed, the development gas (e.g., HBr gas or the like) can now effectively interact with and remove the remaining portions of the unexposed MOR regions 120.

FIG. 7 illustrates the substrate 100 after the gas development process has produced a more defined feature pattern on the substrate 100. In various embodiments, the remaining portions of the unexposed MOR regions 120 (see above, FIG. 6) are removed with a cyclic gas development process including additional gas development process steps as described above with respect to FIG. 4 and additional thermal plasma treatment steps as described above with respect to FIG. 5A. Etch stop layers created by each additional gas development process step are disrupted or removed by a subsequent thermal plasma treatment step, which is then followed by another gas development process step to further remove portions of the unexposed MOR regions 120. This cycle of development and thermal plasma treatment steps is continued until the remaining portions of the unexposed MOR regions 120 are sufficiently or completely removed.

After completion of the cyclic process, the patterned MOR layer 112 now comprises the exposed MOR regions 125 and exhibits well-defined openings 155 that extend down to the underlying layer 104. These openings 155 correspond to the areas where the undesired MOR material has been completely removed, creating a clear path to the underlying layer 104. In one or more embodiments, the size and shape of these openings 155 closely match the intended pattern (feature pattern) from the original photo mask 108 used in the exposure step (see above, FIG. 2). The openings 155 may be utilized for further etching or deposition processes.

FIGS. 8 and 9 illustrate experimental results for an etch scheme on an unexposed MOR layer using a first gas development step, a thermal plasma treatment step, and a second gas development step. The first gas development step was performed using HBr at a temperature in a range of 0 °C to 20 °C for 90 seconds, the plasma of the thermal treatment was generated under a pressure in a range of 300 mTorr to 700 mTorr at a temperature in a range of 0 °C to 20 °C, and the second gas development step was performed using HBr at 10 °C for 60 seconds. FIG. 8 illustrates results of varying the power used to generate the plasma, and FIG. 9 illustrates results of varying the duration of the plasma generation and the gas used. The flow rate of N₂ vibrational gas for the N₂ plasma was kept very high (e.g., in a range of 150 sccm to 1500 sccm) at high pressure (e.g., in a range of 300 mTorr to 700 mTorr) so that a high density of the gas in the chamber would enhance the potential vibrational heat from the N₂.

FIG. 8 illustrates a bar graph comparing thickness remaining after plasma treatments at various plasma generation powers, demonstrating the impact of different plasma generation powers on MOR development. The “No Plasma” bar represents a baseline condition showing a remaining thickness of approximately 55 Å in a process with no plasma (in other words, without a thermal plasma treatment step) but with a total gas development time of 150 seconds. This may demonstrate that an ESL layer forms and causes the thickness remaining to be constant regardless of the subsequent gas development time. The other bars demonstrate the effect of turning plasma on for 15 seconds while modulating the source power from 30 W, 50 W, 200 W, and 300 W. While too low of a plasma generation power may lead to insufficient ESL disruption from a too weak plasma, higher plasma generation powers may lead to diminishing returns or potentially undesired film hardening that impedes MOR etching. As illustrated by the graph, a plasma generation power between 30 W and 500 W, such as 50 W, demonstrated desirable ESL disruption while avoiding MOR film hardening. Plasma power and pressure may be tuned to achieve the most desirable etching results in order to balance disrupting the ESL versus avoiding hardening the bulk MOR film. For example, if plasma power is too weak, running the thermal plasma treatment for a longer time or under a higher pressure may disrupt the ESL more and thereby reduce the thickness remaining.

FIG. 9 illustrates a bar graph of thickness reduction over time during gas development processing with various plasma treatment durations. The data plots thickness remaining of an unexposed MOR resist versus plasma generation time, thereby comparing the effects of different N₂ and Ar plasma exposure times ranging from 5 seconds to 30 seconds. This graph demonstrates the relationship between plasma treatment duration and subsequent material removal efficiency.

As shown by the other bars illustrating N₂ plasma treatment durations of 5 seconds, 8 seconds, 15 seconds, and 30 seconds, and an Ar plasma generation of 15 seconds, performing a thermal plasma treatment by generating plasma enables greater thickness reduction. All of the N₂ plasma treatment results show less thickness remaining than the 15 second Ar plasma treatment, which may indicate that the multi-atomic N₂ molecules with 1 vibrational mode enabled a controlled disruption of the ESL that the monatomic Ar gas with no vibrational modes did not achieve. While the Ar plasma treatment may reduce the thickness remaining, it may do so by removing carbon ligands from the MOR (such as by generating more vacuum ultraviolet (VUV) light in comparison with N₂) that changes the bulk by inducing a densified film. However, this is undesirable as it may lead to an unetchable film.

While too short of a plasma generation time may lead to insufficient ESL disruption, longer plasma exposure times, may lead to diminishing returns or potentially undesired film hardening that impedes MOR etching. As illustrated by the graph, plasma treatment times between 5 seconds and 15 seconds, such as 8 seconds, demonstrated desirable ESL disruption while maintaining MOR film integrity.

FIG. 10 illustrates a schematic diagram of a processing system 400, which may be used to perform the gas development process with thermal plasma treatment step(s) of this disclosure to form a patterned MOR mask. The processing system 400 comprises several components designed to achieve precise control over the gas development process.

The processing system 400 comprises a processing chamber 410 which houses the main processing components. In various embodiments, the processing chamber 410 may be a gas chamber configured to maintain a vacuum environment (or other process specifications) for the gas development process. Within the processing chamber 410, a substrate holder 420 is positioned to support the substrate 100 during the gas development process. In various embodiments, the substrate holder 420 is coupled to a temperature control system 460 to control the temperature of the substrate 100 during the gas development process. In some embodiments, the substrate holder 420 comprises a vacuum chuck or an electrostatic chuck (ESC), and the temperature control system 460 comprises a resistive heater. In other embodiments, the substrate holder 420 and the temperature control system 460 comprise cooling elements to further control the temperature of the substrate 100 as desired. In some embodiments, the heating and cooling elements are parts of the processing chamber 410. In one or more embodiments, the substrate holder 420 is any device suitable for holding the substrate 100 during the gas development process, and the substrate holder 420 may be conductive and electrically connected to a system ground (a reference potential).

At the top of the processing chamber 410 is a top electrode 430. The top electrode 430 comprises a gas inlet 432 for introducing various gases into the processing chamber 410 from a gas system 440. Additionally, the processing chamber 410 may further comprise additional gas inlets besides the gas inlet 432. For example, as many gas inlets may be used for as many different gases are used to form the gas mixtures used in the gas development process. In some embodiments, as few as a single gas inlet may be used. In other embodiments, as many as ten gas inlets may be used. In various embodiments, the top electrode 430 may be electrically coupled with an RF power supply 434 to generate the plasma 140 in the processing chamber 410. For example, an RF bias may be applied to the top electrode 430 to generate the plasma 140.

In various embodiments, the top electrode 430 is a showerhead gas injection system having a gas distribution assembly, and one or more gas distributions plates or conduits coupled to the gas distribution assembly and configured to form one or more gas distribution plenums or supply lines. In further embodiments, the top electrode 430 comprises a branching gas distribution network designed to reduce or minimize gas distribution volume. The processing system 400 may be used to implement various embodiment gas development processes of this disclosure, such as in the processing methods described below using the flowcharts of FIGS. 11-12. Additionally, the processing system 40 may be capable of implementing the gas development process as previously described using FIGS. 4, 5A, 6, and 7 above.

The gas delivery of the processing system 40 is controlled by a gas system 440. This system manages the flow of various gases, such as a development gas 442 and a multi-atomic process gas 444. Additionally, the various gases (442 and 444) may be as described for the development gas and multi-atomic gas in FIGS. 4, 5A, 6, and 7 above. In various embodiments, a purge gas may be provided by the gas system 440, such as an inert gas used to purge the processing chamber 410 during various steps of the gas development process of this disclosure. In various embodiments, the gas system 440 may be configured to supply as many different gases as desired. The gas system 440 may comprise various components such as high-pressure gas canisters, valves (e.g., throttle valves), pressure sensors, gas flow sensors, vacuum pumps, pipes, and electronically programmable controllers. The gas system 440 may also be capable of regulating partial pressures of the gases entering the processing chamber 410 to be used in either the gas development process (in other words, the etching process) or the thermal treatment process of the overall gas development process.

In some embodiments, the processing chamber 410 comprises a remote plasma generator or remote radical generator configured to supply the processing chamber 410 with excited, radical or metastable species, or combinations thereof for use in the plasma 140. In those embodiments, a power source may be used by the plasma generator or the remote radical generator to generate the excited, radical, or metastable species, or combinations thereof. In some embodiments, the power source is capable of supplying a source power between, for example, 5 W and 5000 W.

The temperature of the gas development process may be regulated by the temperature control system 460, which works in conjunction with the heating and cooling elements of the processing chamber 410 or the substrate holder 420 to control the desired substrate temperature. For example, the temperature control system 460 may be capable of achieving temperatures between about −10 °C and 35 °C.

To control the pressure within the processing chamber 410, the processing system 400 comprises a vacuum pump 470 connected to the processing chamber 410 through a gate valve 472. This setup allows for precise control of the chamber pressure during the gas development process. For example, the gas development process may configure pressures within the processing chamber 410 using the vacuum pump 470 and the gate valve 472 between about 20 mTorr and about 90,000 mTorr.

The entire processing system 400 may be managed by a controller 480, which may be coupled to a memory 485. The controller 480 coordinates the operation of all system components, while the memory 485 stores process recipes, parameters, and other relevant data of the gas development process. The controller 480 and the memory 485 may be any suitable conventional device known in the art and capable of performing the functions described above. For example, the controller 480 may be a programmable processor, microprocessor, computer, or the like. Although the controller 480 is illustrated as a single element for illustrative purposes, the controller 480 may include additional elements or be part of a single element. The controller 480 may be programmable by instructions stored in the memory 485, which may include software, firmware, hardware, or a combination thereof. In some embodiments, the memory 485 stores instructions to perform a first gas development process on unexposed MOR material of a substrate within the processing chamber 410 as described above with respect to FIG. 4, disrupt an etch stop layer formed during the first gas development process using a thermal plasma treatment performed with the multi-atomic process gas 444 as described above with respect to FIG. 5A, and perform a second gas development process on the unexposed MOR material below the etch stop layer as described above with respect to FIG. 6.

By carefully controlling the gas flow rates through the different inlets, the characteristics of the various gases, substrate temperature, partial pressures of the components of the various gases of the gas development process, and chamber pressure, the processing system 400 can selectively remove undesired portions of the MOR layer (e.g., exposed MOR material) with precisely controlled processing parameters and improved etch selectivity. Further, the gas development process may be capable of tailoring the MOR layer to remove remnants or undesired portions of the MOR layer to achieve the feature pattern desired to have been achieved by a previous photolithography step and form a patterned MOR mask which may be used as an etch mask in subsequent processing steps.

The processing system 400 illustrates an embodiment capable of generating a capacitively coupled plasma (CCP), but the processing system 400 is one example only. In various embodiments, the processing chamber 410 may be configured to sustain inductively coupled plasma (ICP) with RF source power coupled to a planar coil over a top dielectric cover. Alternatively, other suitable configurations such as electron cyclotron resonance (ESR) plasma sources and/or a helical resonator may be used. The RF power supply 434 may be used to supply continuous wave (CW) or pulsed RF power to sustain the plasma. Gas inlets and outlets may be coupled to sidewalls of the processing chamber 410, and pulsed RF power sources and pulsed DC power sources may also be used in some embodiments. In various embodiments, the RF power, chamber pressure, substrate temperature, gas flow rates and other gas development processing parameters may be implemented in accordance with a respective process recipe for an embodiment of the gas development process of this disclosure.

FIG. 11 illustrates a process flow chart diagram of a method 500 for gas development, in accordance with some embodiments. In step 510, a first part of a first region of a metal oxide resist (MOR) layer is removed with a first gas development process, as described above with respect to FIG. 4. In step 520, an etch stop layer formed over a second part of the first region is disrupted with a plasma treatment using a multi-atomic gas having vibrational modes, as described above with respect to FIG. 5A. In step 530, the second part of the first region is removed with a second gas development process, as described above with respect to FIGS. 6 and 7.

FIG. 12 illustrates a process flow chart diagram of a method 600 for gas development of a metal oxide photoresist, in accordance with some embodiments. In step 610, a metal oxide resist layer is exposed to light through a photomask, as described above with respect to FIGS. 2 and 3. In step 620, portions of non-exposed regions of the metal oxide resist layer are selectively removed with a first etch process, as described above with respect to FIG. 4. In step 630, an etch stop layer formed over remaining portions of the non-exposed regions is removed with a plasma generated using a gas having at least one vibrational mode, as described above with respect to FIG. 5A. In step 640, the remaining portions of the non-exposed regions are selectively removed with a second etch process, as described above with respect to FIGS. 6 and 7.

Example embodiments of the disclosure are summarized here. Other embodiments can also be understood from the entirety of the specification as well as the claims filed herein.

Example 1. A method for gas development, the method including: removing a first part of a first region of a metal oxide resist (MOR) layer with a first gas development process; disrupting an etch stop layer formed over a second part of the first region with a plasma treatment using a multi-atomic gas having vibrational modes; and removing the second part of the first region with a second gas development process.

Example 2. The method of example 1, where the first gas development process includes flowing organic or inorganic acids including acetic acid, chloroacetic acid groups, bromoacetic acid groups, fluoroacetic acid groups, acetylacetone, hexafluoroacetylacetone, HBr, HCl, or HI.

Example 3. The method of one of examples 1 or 2, where the first gas development process is performed under a pressure in a range of 50 mTorr to 5000 mTorr.

Example 4. The method of one of examples 1 to 3, where the first gas development process is performed at a temperature in a range of −50 °C to 100 °C.

Example 5. The method of one of examples 1 to 4, where the multi-atomic gas includes nitrogen, SO₂, or CO₂.

Example 6. The method of one of examples 1 to 5, where the plasma treatment includes generating plasma with a power in a range of 30 W to 500 W.

Example 7. The method of one of examples 1 to 6, where the plasma treatment includes generating plasma for a duration in a range of 5 seconds to 15 seconds.

Example 8. The method of one of examples 1 to 7, where the plasma treatment is performed under a pressure in a range of 50 mTorr to 700 mTorr.

Example 9. A method for gas development of a metal oxide photoresist, the method including: exposing a metal oxide resist layer to light through a photomask; selectively removing portions of non-exposed regions of the metal oxide resist layer with a first etch process; removing an etch stop layer formed over remaining portions of the non-exposed regions with a plasma generated using a gas having at least one vibrational mode; and selectively removing the remaining portions of the non-exposed regions with a second etch process.

Example 10. The method of example 9, where the gas includes nitrogen.

Example 11. The method of one of examples 9 or 10, where the gas includes SO₂.

Example 12. The method of one of examples 9 to 11, where the gas includes CO₂.

Example 13. The method of one of examples 9 to 12, where the first etch process and the second etch process include etching the remaining portions of the non-exposed regions with HBr gas.

Example 14. The method of one of examples 9 to 13, where the first etch process and the second etch process are performed at a temperature in a range of −50 °C to 100 °C.

Example 15. The method of one of examples 9 to 14, where the gas is flowed at a flow rate in a range of 150 sccm to 1500 sccm.

Example 16. A system including: a process chamber configured to receive a substrate having an exposed metal oxide resist (MOR) layer; a gas delivery system coupled with the process chamber, the gas delivery system being configured to supply a development gas and a multi-atomic process gas; and a controller coupled with the process chamber, the gas delivery system, and a memory storing instructions to be executed in the controller, the instructions when executed causing the controller to: perform a first gas development process on unexposed MOR material of the exposed MOR layer with the development gas, disrupt an etch stop layer formed during the first gas development process using a plasma treatment performed with the multi-atomic process gas, and perform a second gas development process on a portion of the unexposed MOR material below the etch stop layer with the development gas.

Example 17. The system of example 16, where the development gas includes HBr, HCl, or HI.

Example 18. The system of one of examples 16 or 17, where the multi-atomic process gas includes N₂.

Example 19. The system of example 18, where the plasma treatment includes flowing N₂ at a flow rate in a range of 150 sccm to 1500 sccm.

Example 20. The system of one of examples 16 to 19, where the first gas development process, the plasma treatment, and the second gas development process are performed at a temperature in a range of −50 °C to 100 °C and under a pressure in a range of 50 mTorr to 700 mTorr.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for gas development, the method comprising:
removing a first part of a first region of a metal oxide resist (MOR) layer with a first gas development process;
disrupting an etch stop layer formed over a second part of the first region with a plasma treatment using a multi-atomic gas having vibrational modes; and
removing the second part of the first region with a second gas development process.

2. The method of claim 1, wherein the first gas development process comprises flowing organic or inorganic acids including acetic acid, chloroacetic acid groups, bromoacetic acid groups, fluoroacetic acid groups, acetylacetone, hexafluoroacetylacetone, HBr, HCl, or HI.

3. The method of claim 1, wherein the first gas development process is performed under a pressure in a range of 50 mTorr to 5000 mTorr.

4. The method of claim 1, wherein the first gas development process is performed at a temperature in a range of −50 °C to 100 °C.

5. The method of claim 1, wherein the multi-atomic gas comprises nitrogen, SO₂, or CO₂.

6. The method of claim 1, wherein the plasma treatment comprises generating plasma with a power in a range of 30 W to 500 W.

7. The method of claim 1, wherein the plasma treatment comprises generating plasma for a duration in a range of 5 seconds to 15 seconds.

8. The method of claim 1, wherein the plasma treatment is performed under a pressure in a range of 50 mTorr to 700 mTorr.

9. A method for gas development of a metal oxide photoresist, the method comprising:
exposing a metal oxide resist layer to light through a photomask;
selectively removing portions of non-exposed regions of the metal oxide resist layer with a first etch process;
removing an etch stop layer formed over remaining portions of the non-exposed regions with a plasma generated using a gas having at least one vibrational mode; and
selectively removing the remaining portions of the non-exposed regions with a second etch process.

10. The method of claim 9, wherein the gas comprises nitrogen.

11. The method of claim 9, wherein the gas comprises SO₂.

12. The method of claim 9, wherein the gas comprises CO₂.

13. The method of claim 9, wherein the first etch process and the second etch process comprise etching the remaining portions of the non-exposed regions with HBr gas.

14. The method of claim 9, wherein the first etch process and the second etch process are performed at a temperature in a range of −50 °C to 100 °C.

15. The method of claim 9, wherein the gas is flowed at a flow rate in a range of 150 sccm to 1500 sccm.

16. A system comprising:
a process chamber configured to receive a substrate having an exposed metal oxide resist (MOR) layer;
a gas delivery system coupled with the process chamber, the gas delivery system being configured to supply a development gas and a multi-atomic process gas; and
a controller coupled with the process chamber, the gas delivery system, and a memory storing instructions to be executed in the controller, the instructions when executed causing the controller to:
perform a first gas development process on unexposed MOR material of the exposed MOR layer with the development gas,
disrupt an etch stop layer formed during the first gas development process using a plasma treatment performed with the multi-atomic process gas, and
perform a second gas development process on a portion of the unexposed MOR material below the etch stop layer with the development gas.

17. The system of claim 16, wherein the development gas comprises HBr, HCl, or HI.

18. The system of claim 16, wherein the multi-atomic process gas comprises N₂.

19. The system of claim 18, wherein the plasma treatment comprises flowing N₂ at a flow rate in a range of 150 sccm to 1500 sccm.

20. The system of claim 16, wherein the first gas development process, the plasma treatment, and the second gas development process are performed at a temperature in a range of −50 °C to 100 °C and under a pressure in a range of 50 mTorr to 700 mTorr.
